(19) United States
(12) Patent Application Publication
(10) Pub. No.: US 2018/0197841 A1
(43) Pub. Date: Jul. 12, 2018

(54) LIGHTING MODULE

(71) Applicant: OSRAM Opto Semiconductors GmbH, Regensburg (DE)

(72) Inventors: Tony ALBRECHT, Bad Abbach (DE); Tamas LAMFALUSI, Regensburg (DE); Roland SCHULZ, Regensburg (DE); Frank SINGER, Regenstauf (DE); Matthias SABATHIL, Regensburg (DE)

(21) Appl. No.: 15/328,007

(22) PCT Filed: Jul. 7, 2015
(86) PCT No.: PCT/EP2015/065475

§ 371 Date: Jan. 20, 2017

(30) Foreign Application Priority Data
Jul. 24, 2014 (DE) 10 2014 110 470.6

(51) Int. Cl. H01L 25/075; H01L 33/60

(52) U.S. Cl. CPC H01L 25/0753; F21K 9/64; H01L 33/60

(57) ABSTRACT

The invention relates to a lighting module (1) comprising an assembly body (3) extending between a rear side (31) and a front side (30) opposite the rear side, and comprising a plurality of semiconductor components (2) provided for generating radiation, wherein: the assembly body has a plurality of recesses (35) on the rear side, in which the semiconductor components are arranged; the assembly body is permeable to the radiation generated in the semiconductor components, and said radiation passes out of the front side of the assembly body; a contact layer (5) is arranged on the rear side of the assembly body, to which the semiconductor components are connected in an electrically conductive manner via connecting lines; and a reflector layer (6) is arranged on the rear side of the assembly body, said reflector layer entirely covering at least the recesses.

The present application relates to a lighting module.

Illuminants on the basis of light-emitting diodes (LEDs) are more frequently used for general lighting systems due to the efficient generation of radiation. Individual LEDs can be mounted in a row on a circuit board, for example. The radiation characteristic can be influenced and shaped by additional components such as lenses or reflectors. However, this results in a comparatively elaborate structure involving high manufacturing costs.

One object is to provide a lighting module, which can be produced in a simple and cost-efficient manner, and which at the same time has a high homogeneity in luminance distribution.

Inter alia, said object is achieved by means of a lighting module according to claim 1. Further embodiments and developments are the subject-matter of the dependent patent claims.

According to at least one embodiment of the lighting module, the lighting module comprises an assembly body, which extends between a rear side and a front side located opposite the rear side. In particular, the assembly body is configured to be transmissive to radiation in the visible spectral range. During operation of the lighting module, the radiation generated in the lighting module in particular exits the front side of the assembly body.

According to at least one embodiment of the lighting module, the lighting module comprises a plurality of semiconductor components which are provided for the generation of radiation. For example, during operation, the semiconductor components generate radiation in the ultraviolet, visible or infrared spectral range. For example, the semiconductor components comprise in each case at least one semiconductor chip provided for the generation of radiation.

According to at least one embodiment of the lighting module, the assembly body comprises a plurality of recesses on the rear side in which the semiconductor components are arranged. In particular, exactly one semiconductor component is arranged in each recess. For example, the semiconductor components are arranged completely within the recesses. The semiconductor components arranged in the recesses thus do not protrude from the rear side of the assembly body. During operation of the lighting module, the radiation generated in the semiconductor components can enter the assembly body via the side surfaces and/or a bottom surface of the recesses and exit the front side of the assembly body.

According to at least one embodiment of the lighting module, a contact layer is arranged on the rear side of the assembly body. The contact layer is provided to electrically contact the semiconductor components. For example, the semiconductor components are connected to one another by means of the contact layer in a series connection, a parallel connection or a combination of a series connection and a parallel connection. In particular, the contact layer adjoins the assembly body. For example, the contact layer is a layer deposited on the assembly body.

In particular, the contact layer is designed to be reflective for the radiation generated in the semiconductor components. In the present application, an element or a material is, in particular, considered to be reflective if it has a reflectivity of at least 60% for the peak wavelength of the radiation generated by the semiconductor components.

For example, contact lines are formed by means of the contact layer, which electrically conductively connect semiconductor components which are arranged adjacent to one another. In a plan view of the rear side of the assembly body, the contact layer may cover the rear side over large areas, for example with a cover ratio of at least 50%.

For example, the contact layer and the recesses are arranged next to one another without overlapping in a plan view of the rear side of the assembly body. Thus, the contact layer does not extend into the recesses of the assembly body.

According to at least one embodiment of the lighting module, the semiconductor components are connected to the contact layer in an electrically conductive manner via connection lines. The connection lines are configured as bond wires, for example. For example, each semiconductor component is electrically conductively connected to the contact layer via exactly two connection lines.

According to at least one embodiment of the lighting module, a reflector layer is arranged on the rear side of the assembly body. The reflector layer is designed to reflect particularly the radiation generated by the semiconductor components during operation. For example, the reflector layer is designed to reflect in a diffuse manner. For example, the reflector layer is formed at a distance from the semiconductor components. In particular, the reflector layer is not directly adjacent to the semiconductor components in any place. For example, the reflector layer has an electrically insulating design. For example, the reflector layer contains a polymer material which is enriched with particles which increase the reflectivity. The reflector layer covers the recesses at least partially. In particular, the reflector layer may also completely cover the recesses. The reflector layer may be divided in individual, discontiguous sub-regions. For example, exactly one sub-region is assigned to each recess. As an alternative, the reflector layer may also extend across two or more recesses and in particular also completely or essentially cover the rear side of the assembly body, for example with a cover ratio of at least 90%.

In at least one embodiment of the lighting module, the lighting module comprises an assembly body and a plurality of semiconductor components which are provided for the generation of radiation. The assembly body extends between a rear side and a front side opposite the rear side. At the rear side, the assembly body has a plurality of recesses in which the semiconductor components are arranged. The assembly body is transmissive to the radiation generated in the semiconductor components and exits on the front side of the assembly body. A contact layer is arranged on the rear side of the assembly body, the semiconductor layers being electrically conductively connected to the contact layer via connection lines. A reflector layer is arranged on the rear side of the assembly body, which at least covers the recesses completely.

According to at least one embodiment of the lighting module, the reflector layer and the contact layer together cover at least 90% of the rear side of the assembly body with a reflective material. In other words, either the reflector layer or the contact layer or both the reflector layer and the contact layer are located on at least 90% of the surface area on the rear side of the assembly body. For example, the reflector layer and the contact layer cover the entire part of the rear side which extends within an outer border around the outermost semiconductor components of the lighting module. In other words, the rear side of the assembly body is not covered by a reflective material in the edge regions at the most.

According to at least one embodiment of the lighting module, interspaces between the semiconductor components and the assembly body are at least partially filled with a radiation-transmissive enclosure. For example, the radiation-transmissive enclosure contains a polymer material such as a silicone or an epoxy.

For example, the enclosure adjoins the side surfaces of the recesses of the assembly body at least in places. For example, the reflector layer adjoins the enclosure on the side of the enclosure facing away from the front side of the assembly body. For example, the enclosure adjoins the connection lines. In particular, the enclosure may completely cover the connection lines in a plan view of the rear side of the assembly body.

According to at least one embodiment of the lighting module, the semiconductor components are semiconductor chips without housing. Thus, the semiconductor components per se do not comprise a housing surrounding the respective semiconductor chip. In particular, the semiconductor chips without housing are electrically conductively connected to the contact layer via connection lines in the form of bond wires.

According to at least one embodiment of the lighting module, the semiconductor chips comprise a radiation-transmissive substrate, respectively. For example, the substrate contains sapphire or silicon carbide. For example, at least one part of the radiation exits the semiconductor chip through the substrate during operation of the semiconductor chip and enters the assembly body via side surfaces of the recesses. For example, at least 50% or at least 70% of the radiation generated in the semiconductor chip exits the semiconductor chip through the substrate.

According to at least one embodiment of the assembly body, the assembly body has an elongate design. For example, the extension of the assembly body along a longitudinal extension direction is at least five times or at least ten times the size of a maximum extension in a cross-section running vertically thereto.

According to at least one embodiment of the lighting module, a front side of the assembly body runs in a curved manner at least in places. For example, the entire front side or at least a part of the front side of the assembly body is convexly curved or concavely curved in a plan view of the front side. In particular, the front side of the assembly body runs curved in a cross-section which runs perpendicular to the longitudinal extension direction of the lighting module. For example, both the front side and the rear side are curved.

According to at least one embodiment of the lighting module, the assembly body has a basic shape of a tubular segment. For example, the assembly body has the basic shape of a half tube. Here, the term tube does not imply a restriction to a cross-section having inner surfaces and/or outer surfaces shaped as circular segments. For example, the inner surfaces and/or outer surfaces may also be shaped to be parabolic or ellipsoid in places in a cross-section. In a plan view of the front side of the assembly body, this body is curved convexly. At any place perpendicular to the front side, the assembly may have the same thickness or at least essentially the same thickness, for example with a deviation of 20% at the most.

According to at least one embodiment of the lighting module, the assembly body has the basic shape of a cylinder segment. For example, the front side of the assembly body has a curved design and the rear side of the assembly body has a flat design. Such an assembly body may fulfill the function of a cylinder lens.

According to at least one embodiment of the lighting module, a radiation conversion material is located in a beam path between the semiconductor components and a radiation exit surface of the lighting module. The radiation conversion material is provided for the at least partial conversion of a primary radiation with a first peak wavelength generated by the semiconductor components into secondary radiation with a second peak wavelength different from the first peak wavelength. The radiation conversion material may contain one or multiple luminescent substances which generate radiation in the red, yellow, green or blue spectral range. For example, the primary radiation is in the blue spectral range and the secondary radiation is in the yellow spectral range so that overall the lighting module radiates radiation that appears to be white to the human eye.

For example, the radiation conversion material is arranged at a distance from the semiconductor components. That means that the radiation conversion material does not directly adjoin the semiconductor components at any place.

According to at least one embodiment of the lighting module, a minimum distance between the semiconductor components and the radiation conversion materials is at least 10% of the center-to-center distance between two adjacent semiconductor components, in particular between the two semiconductor components which are respectively located in close proximity. For example, the minimum distance is between including 10% and including 80% of the center-to-center distance. The greater the minimum distance between the semiconductor components and the radiation conversion material in relation to the center-to-center distance between neighboring semiconductor components, the easier a homogenous luminance distribution and/or uniform color impression can be achieved.

According to at least one embodiment of the lighting module, the lighting module comprises a radiation-transmissive body on the front side of the assembly body. The radiation-transmissive body particularly forms the radiation exit surface of the lighting module. For example, the radiation-transmissive body is designed as a tubular segment-type body which encloses the assembly body on the side of the assembly body facing the radiation exit surface.

Thus, the radiation-transmissive body is arranged relative to the assembly body in such a way that each beam path from the semiconductor components to the radiation exit surface runs through the radiation-transmissive body.

According to at least one embodiment of the lighting module, the conversion material is arranged between the assembly body and the radiation-transmissive body. Thus, the radiation conversion element is arranged dimensionally spaced from both the semiconductor components and the radiation exit surface. For example, the radiation conversion material is applied on the front side of the assembly body or on an inner side of the radiation-transmissive body facing the assembly body. The radiation-transmissive body protects the radiation conversion material from external mechanical stress. The risk of scratching the radiation conversion material and a resulting locally reduced radiation conversion is thus prevented in a simple manner.

According to at least one embodiment of the lighting module, the radiation-transmissive body has a roughening on the radiation exit surface. In particular, the roughening is designed in such a way that radiation conversion material can not be perceived or at least only be perceived to a limited extent by the human eye through the radiation-transmissive body in the switched-off state of the lighting module.

According to at least one embodiment of the lighting module, the assembly body has a maximum extension along a direction running perpendicular to the longitudinal extension direction of the assembly body, which is at least 20% and at most 50% of the maximum extension of the radiation-transmissive body along this direction. Thus, the radiation-transmissive body has a greater extension than the assembly body along said direction.

According to at least one embodiment of the lighting module, the assembly body contains a glass or consists of a glass. Such an assembly body can be produced in a simple and cost-efficient manner, for example by means of pultrusion.

According to at least one embodiment of the lighting module, the lighting module is formed for insertion into a socket for a fluorescent tube. Thus, the lighting module is provided to replace a fluorescent tube without that modifications to the mechanical fastening mechanism need be made to that end. Such LED based lighting modules which replace conventional lamps, in particular incandescent lamps or discharge lamps, are also called “retrofit”. For example, the lighting module is provided as a replacement of a T8 fluorescent tube, a T5 fluorescent tube or a T2 fluorescent tube.

The following effects, in particular, can be achieved with the described lighting module.

The use of circuit boards can be omitted, due to the arrangement of the semiconductor components in a radiation-transmissive assembly body, which contains a glass, for example. Thus, the assembly body serves as a mechanical carrier and, by means of the contact layer arranged thereon, it also serves for electrically contacting the semiconductor components. Furthermore, in contrast to a circuit board, the assembly body may additionally achieve a targeted shaping of the radiation characteristic and fulfill the function of a reflector or a lens, for example. Additional elements for shaping the radiation characteristic can be omitted.

Furthermore, by means of the radiation radiated through the assembly body, a particularly homogenous luminance distribution can be achieved in a simple manner so that the individual semiconductor components cannot or only to a limited extent be perceived as individual spaced light sources by the human eye. Furthermore, by means of semiconductor components in the form of semiconductor chips without housing with a radiation-transmissive substrate, a particularly high radiation proportion can be coupled into the assembly body via the side surfaces of the recesses of the assembly body. The homogeneity of the luminance distribution can thus be increased even further.

Furthermore, different performance categories can be achieved for the lighting module in a simple manner by different distances of the semiconductor components and/or a different number of semiconductor components. Furthermore, an increase in brightness of the semiconductor components may be responded to in a simple manner.

Furthermore, the lighting module can be produced in an especially compact and cost-efficient manner.

Further features, embodiments and developments result from the following description of the exemplary embodiments in conjunction with the Figures.

The Figures show in:

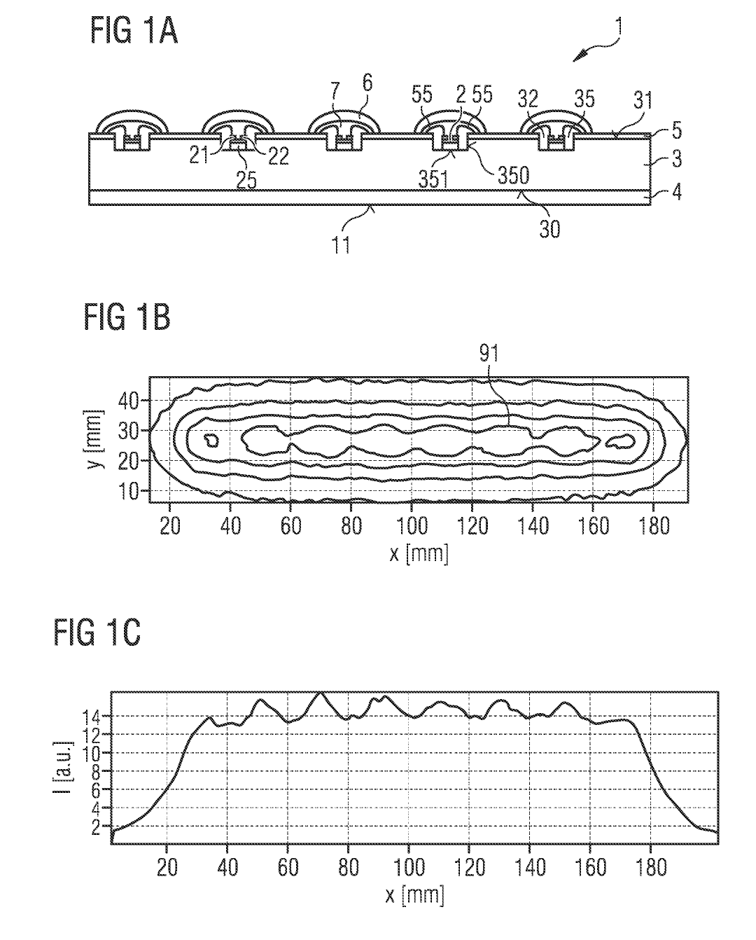

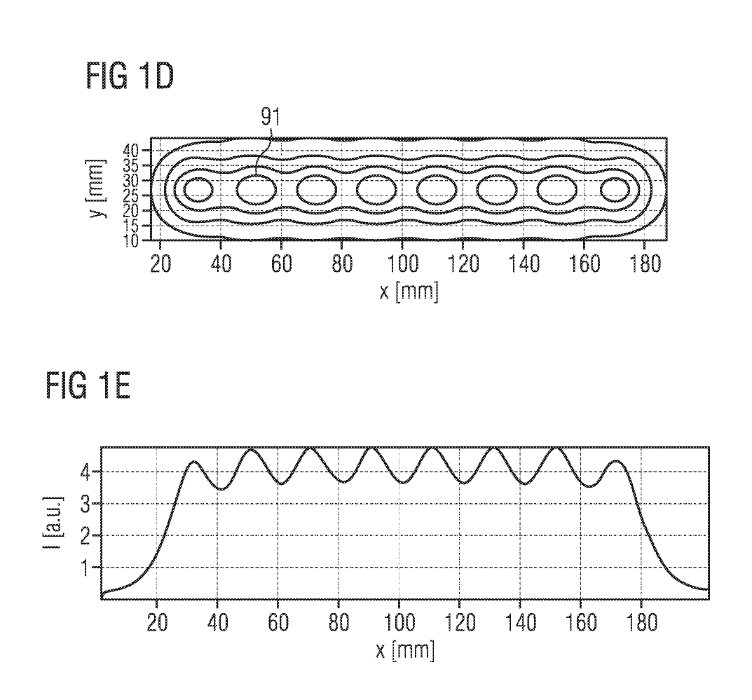

FIG. 1A a first exemplary embodiment for a lighting module in a schematic sectional view;

FIGS. 1B and 1C simulation results for the distribution of the illuminance I as a level curve diagram (FIG. 1B) as well as a function along a longitudinal extension direction in arbitrary units in FIG. 1C;

FIGS. 1D and 1E comparative simulations for a lighting module with LEDs arranged on a circuit board, wherein the illustration is analogous to FIGS. 1B and 1C, respectively;

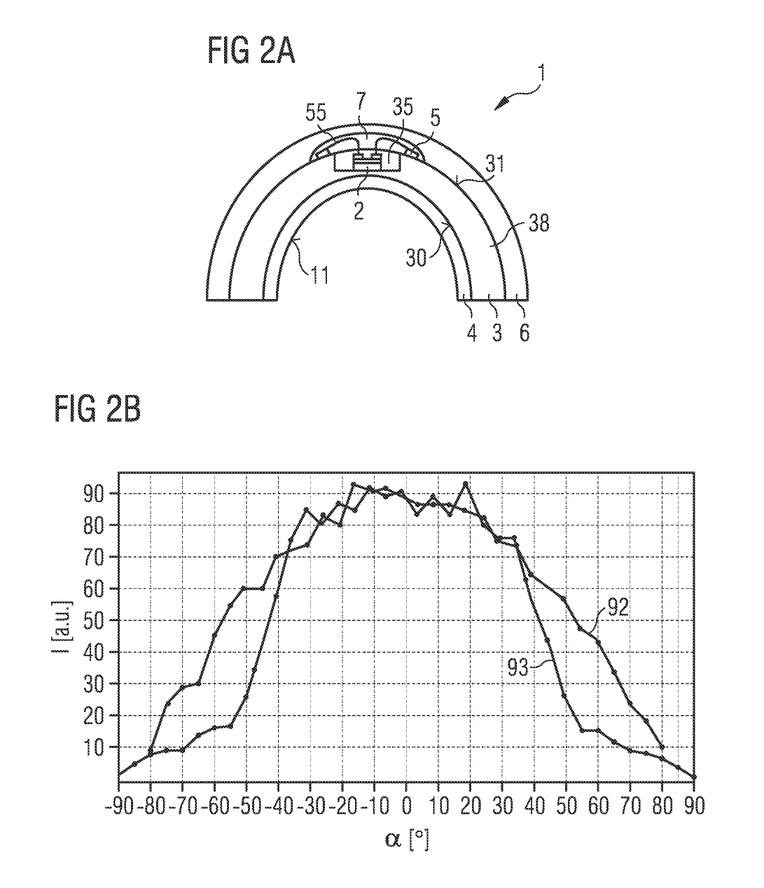

FIG. 2A a second exemplary embodiment for a lighting module in a schematic sectional view;

FIG. 2B associated simulation results for the angle-dependent intensity distribution along a longitudinal extension direction and a transversal direction running perpendicular thereto;

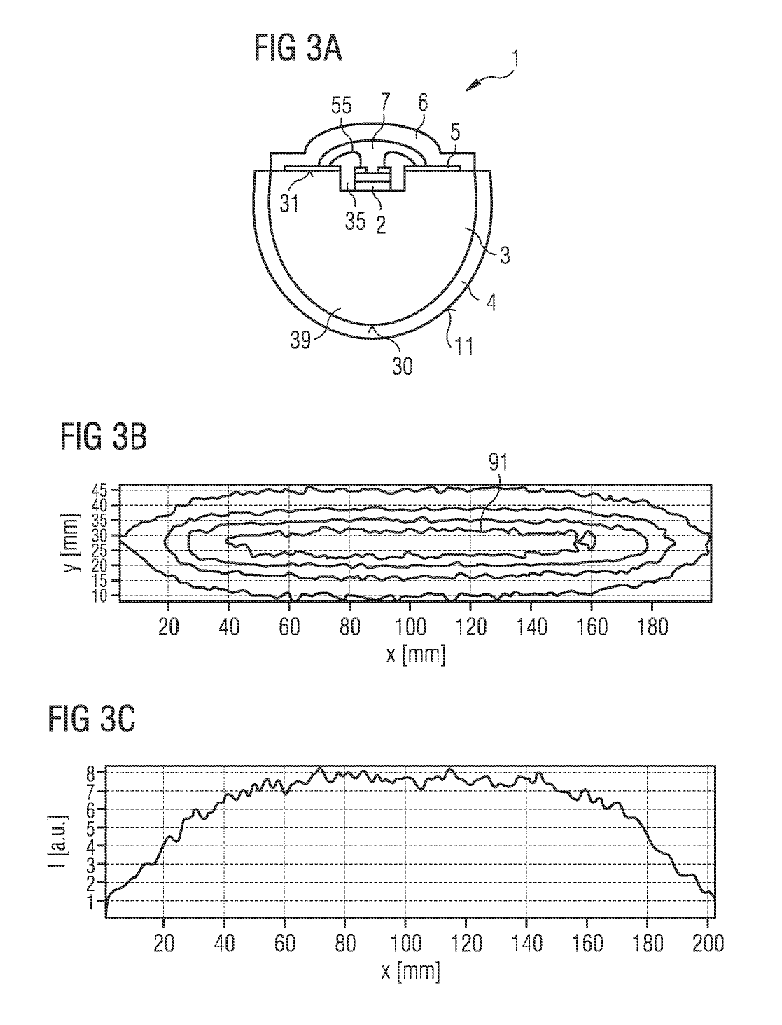

FIG. 3A a third exemplary embodiment for a lighting module in a schematic sectional view;

FIGS. 3B and 3C associated simulation results for the distribution of illuminance I as a level curve diagram (FIG. 3B) and as a function along the longitudinal extension direction (FIG. 3C); and

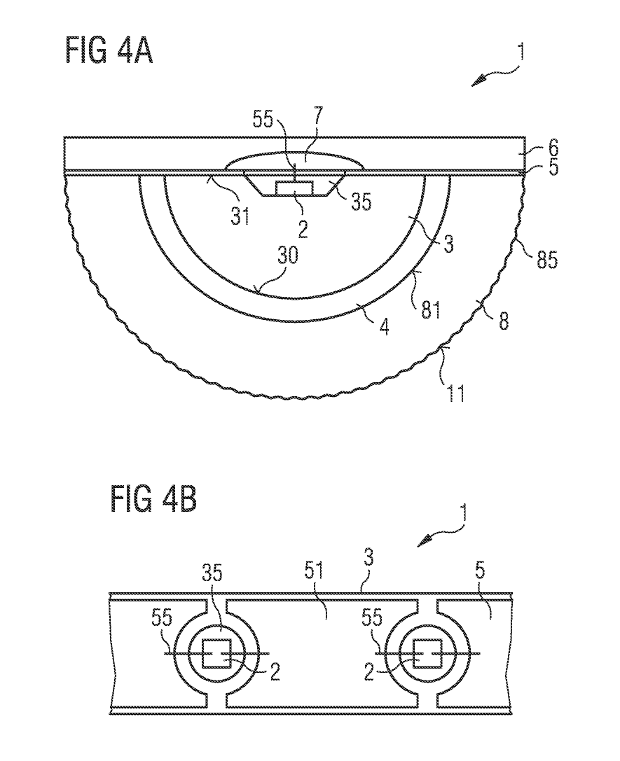

FIGS. 4A and 4B a fourth exemplary embodiment for a lighting module in a schematic sectional view (FIG. 4A) and in a plan view (FIG. 4B).

Like, similar or equivalent elements are denoted with like reference numerals.

The Figures are in each case schematic illustrations and thus not necessarily made to scale. Comparatively small elements and in particular layer thicknesses can be illustrated in an exaggerated size for illustration purposes and/or for a better understanding.

FIG. 1A shows a first exemplary embodiment for a lighting module in a schematic sectional view. The lighting module 1 comprises an assembly body 3, which extends in a vertical direction between a front side 30 and a rear side 31. The assembly body comprises a plurality of recesses 35 on the rear side 31.

Furthermore, the lighting module 1 comprises a plurality of semiconductor components 2. The semiconductor components 2 are in each case arranged in one of the recesses 35. In particular, the semiconductor components 2 do not protrude from the rear side 31 in a vertical direction. The semiconductor components 2 each comprise a first connection surface 21 and a second connection surface 22 for electrically contacting the semiconductor components. The first connection surface 21 and the second connection surface 22 are arranged on the side of the semiconductor components 2 facing away from the front side 30 of the assembly body 3. In the production of the lighting module, the first connection surface and the second connection surface are accessible in the assembly body 3 for the electrical contacting by means of connection lines.

A contact layer 5 is formed on the rear side 31 of the assembly body 3. The semiconductor components 2 are electrically conductively connected to the contact layer via connection lines 55, for example bond wires.

For example, the contact layer 5 forms in each case one contact line 51 between neighboring semiconductor components 2. The semiconductor components 2 can thereby be electrically coupled in series in a simple manner. The semiconductor components 2 or groups of the semiconductor components 2 can also be connected in parallel to one another.

The semiconductor components 2 are surrounded by an enclosure 7. In particular, the enclosure fills interspaces 32 between the semiconductor components 2 and the assembly body 3. The enclosure is formed to be transmissive to radiation. For example, the enclosure 7 contains a polymer material such as an epoxy or a silicone. In particular, the enclosure covers the semiconductor components 2 completely in a plan view of the rear side 31. The connection lines 55 are embedded in the enclosure.

Furthermore, the lighting module 1 comprises a reflector layer 6 on the rear side of the assembly body 3. In the exemplary embodiment shown, the reflector layer is divided in individual sub-regions spaced in a lateral direction, i.e. along a main extension plane of the assembly body 3. The sub-regions of the reflector layer 6 in each case completely cover one of the recesses 35. The reflector layer is not directly adjoining the semiconductor components 2 in any place. The enclosure is arranged between the reflector layer and the semiconductor components. The reflector layer 6 adjoins the enclosure on the side of the enclosure facing away from the front side 30 of the assembly body 31.

Furthermore, the lighting module 1 comprises a radiation conversion material 4. The radiation conversion material 4 is arranged at a distance from the semiconductor components 2. In particular, the assembly body 3 is arranged between the semiconductor components 2 and the radiation conversion material 3. The radiation generated by the semiconductor components 2 passes through the assembly body 3 before impinging the radiation conversion material. This may achieve an especially homogenous color impression. In the exemplary embodiment shown, the radiation conversion material is formed on the front side 30 of the assembly body 3, e.g. in the form of a coating.

Preferably, a minimum distance between the semiconductor components and the radiation conversion material 4 is at least 10% of the center-to-center distance between two neighboring semiconductor components 2. Achieving a homogeneous color impression is thus further simplified.

In contrast, the radiation conversion material 4 can also be arranged between the semiconductor components 2 and the assembly body 3, for example on the side surfaces 350 and/or a bottom surface 351 of the recesses 35. As an alternative, the radiation conversion material 4 may also be formed by means of luminescent substances which are embedded in the enclosure 7 of the semiconductor component 2.

The assembly body 3 is designed to be transmissive to the radiation generated by the semiconductor components 2. For example, the assembly body 3 contains a glass or consists of a glass.

During operation of the lighting module 1, the radiation generated in the semiconductor components 2 can be coupled into the assembly body 3 via the enclosure 7 and can exit the front side 30 of the assembly body. The radiation conversion material converts part of the primary radiation generated by the semiconductor components 2 partially into secondary radiation so that the lighting module generates mixed radiation, for example mixed radiation that appears to be white to the human eye. For example, the semiconductor component 2 emits in the blue spectral range and the radiation conversion material converts this radiation partially into radiation in the yellow spectral range. For example, the radiation conversion material contains a luminescent substance which is embedded in a matrix material, for example a polymer material. The radiation conversion material 4 may also contain more than one luminescent substance, wherein the luminescent substances emit radiation in spectral ranges which are different from one another, for example in the red, green and/or yellow spectral range. In the exemplary embodiment shown, the radiation conversion material 4 forms a radiation exit surface 11 of the lighting module 1.

Preferably, the contact layer 5 is designed to be reflective for the radiation generated in the semiconductor components 2. For example, the contact layer 5 contains a metal such as silver. Silver is characterized by an especially high reflectivity in the visible spectral range. As an alternative, even another metal such as aluminum, rhodium, nickel or chromium can be used.

For example, the reflector layer 6 comprises a polymer material which is enriched with particles that increase reflectivity. For example, the particles contain titanium oxide, zirconium oxide or aluminum oxide.

Thus, the reflector layer 6 and the contact layer 5 are designed such that they are formed over large areas on the rear side 31 of the assembly body and prevent radiation from exiting on this side. Preferably, the reflector layer and the contact layer together cover at least 90%, particularly preferably at least 95% of the rear side of the assembly body with a reflective material. In particular, the reflector layer and the contact layer cover the entire part of the rear side which extends within an external border around the outermost semiconductor components of the lighting module.

The semiconductor components 2 can be arranged in a row. For example, all semiconductor components 2 are arranged along a longitudinal extension direction next to one another. As an alternative, the semiconductor components can also be arranged in a two-dimensional, for example matrix-shaped, manner on the assembly body 3.

A center-to-center distance between neighboring semiconductor components 2 is preferably between including 5 mm and including 50 mm, preferably between including 20 mm and including 40 mm.

The semiconductor components 2 are preferably formed as semiconductor chips without housing. Furthermore, the semiconductor components 2 preferably comprise a radiation-transmissive substrate 25. Radiation generated in an active region of the semiconductor components 2 (not explicitly shown) can thus also exit through the side surfaces of the substrate and be coupled into the assembly body via the side surfaces 350 of the assembly body 3. As a result, a homogenous illuminance distribution can be achieved in a simple manner. However, in contrast, semiconductor components 2 can be used which comprise a housing for the semiconductor chips.

Simulation results of a distribution of illuminance I in arbitrary units are illustrated in FIGS. 1B and 1C. Here, the X-axis runs along a longitudinal extension direction and the Y-axis runs transversally thereto. FIG. 1C illustrates the illuminance distribution on a longitudinal sectional view through the semiconductor components 2, i.e. for y=0. The simulations are based upon an arrangement with eight semiconductor chips 2 without housing at a distance of 20 mm, wherein the simulation results relate to a distance of 1 mm from the radiation exit surface 11.

FIG. 1B illustrates a level curve diagram of the illuminance distribution, in which a region of the greatest illuminance 91 is encircled by the innermost level curve. The simulations confirm that due to the light distribution in the assembly body 3, an illuminance prevails even in the interspaces between the semiconductor components 2 which is only slightly smaller than the maximum illuminance. A homogeneous illuminance distribution can thus be achieved without an additional optical element.

In contrast, FIGS. 1D and 1E show analog simulation results for an arrangement of semiconductor components, in which the semiconductor chips are each mounted in a surface-mountable housing, wherein the semiconductor components are mounted on a circuit board. Here, illuminance decreases between neighboring semiconductor components in a comparatively intense manner, so that the individual semiconductor components are perceivable as bright spots by the human eye.

The second exemplary embodiment illustrated in FIG. 2A corresponds essentially to the exemplary embodiment described in conjunction with FIG. 1A. In contrast thereto, the assembly body 3 is formed in the shape of a tubular segment 38. The front side 30 and the rear side 31 of the assembly body 3 each run in a curved manner. The front side is concavely curved in a plan view of the front side 30.

The rear side 31 of the assembly body is designed to be reflecting by means of the reflector layer 6 and the contact layer 5. In the exemplary embodiment illustrated in FIG. 2A, the reflector layer extends completely across the rear side 31. Even in a comparatively small coverage by means of the contact layer 5, the radiation is efficiently reflected on the rear side 31. The contact layer 5 can naturally also cover the rear side 31 of the assembly body 3 over large areas. In this case, the reflector layer 6 may also be formed only in the region of the recesses 35.

Perpendicular to the front side 30, the extension of the assembly body 3 is constant or at least essentially constant. Viewed in the cross-section, the front side 30 and the rear side 31 may have the shape of a circle segment, an ellipse segment or a parabola, for example. The radiation characteristic can be adjusted by means of the shape of the assembly body. In this exemplary embodiment, in addition to its function as a mechanical support, the assembly body 3 also fulfills the function of an optical element in the shape of a curved reflector.

FIG. 2B shows the simulation results of an intensity I depending on angle α along a longitudinal extension direction, illustrated by curve 93, and along a transversal direction running perpendicular thereto, illustrated by a curve 92. In the described embodiment, the full width at half maximum of the angular distribution in the transversal direction is 118.7° and in the longitudinal extension direction 88.2°. By a corresponding selection of the geometry of the assembly body 3, even smaller or wider angular distributions can be achieved.

The third exemplary embodiment illustrated in FIG. 3A corresponds essentially to the second exemplary embodiment described in conjunction with FIG. 2A. In contrast hereto, the assembly body 3 is formed with a curved front side 30 and a flat rear side 31—except for the recesses 35. The assembly body 3 has the basic shape of a cylinder segment 39. Such an assembly body 3 acts as a cylinder lens.

FIGS. 3B and 3C illustrate simulation results of the distribution of illuminance I. With this configuration, an especially homogenous illuminance distribution results in the longitudinal extension direction, which decreases not before toward the edge of the lighting module 1. There is no significant decrease in illuminance between neighboring semiconductor components 2.

The fourth exemplary embodiment illustrated in FIG. 4A corresponds essentially to the third exemplary embodiment described in conjunction with FIG. 3A. In contrast thereto, the lighting module 1 has a radiation-transmissive body 8. The radiation-transmissive body 8 forms the radiation exit surface 11 of the lighting module 1. For example, the radiation-transmissive body contains a glass or consists of a glass. The radiation-transmissive body is designed in such a way and arranged relative to the assembly body 3 that radiation generated in the semiconductor components 2 needs to pass the radiation-transmissive body 8 before it can exit the radiation exit surface 11 of the lighting module. An inner surface 81 of the radiation-transmissive body 8 is adapted to the front side 30 of the assembly body in such a way that no gap remains or at least only a small gap is present between the assembly body 3 and the radiation-transmissive body 8. If required, the gap can be filled with a filler material (not explicitly shown in the Figures).

For example, the radiation-transmissive body 8 is formed as a half tube which encloses an assembly body 3 formed as a half cylinder on the front side 30 of the assembly body.

The radiation conversion material 4 is arranged between the assembly body 3 and the radiation-transmissive body 8. The radiation-transmissive body 8 thus protects the radiation conversion material 4 against mechanical stress. The risk of scratching of the radiation conversion material 4, which could lead to a locally reduced radiation conversion, is thus avoided.

FIG. 4B schematically shows a plan view of the semiconductor component 2. The contact layer 5 in each case forms contact lines 51 between neighboring semiconductor components 2. This way, the semiconductor components 2 are electrically coupled in series to one another in a simple manner. Furthermore, the contact layer 5 is designed such that it covers the rear side 31 of the assembly body 3 over large areas. The contact layer 5 may further also adjoin the radiation-transmissive body 8 in sections. The reflector layer 6 can be formed over the complete area on the rear side 31 of the assembly body or, as described in conjunction with FIG. 1A, cover the rear side 31 only in places, in particular in the region of the recesses 35.

The radiation-transmissive body 8 has a roughening 85 on the radiation exit surface 11. Homogeneity of the luminance distribution can be further increased by means of the roughening. Furthermore, the roughening 85 effects that the radiation conversion material 4 can not or only to a limited extent be perceived by the human eye through the radiation-transmissive body 8 in the switched-off state of the lighting module. This results in a whitish impression in a plan view of the lighting module 1 in the switched-off state.

In the production of the described lighting modules, an assembly body 3 which can be produced in a simple and cost-efficient manner, for example a glass body formed by pultrusion, can be equipped with the semiconductor components 2. By means of the contact layer 5, the assembly body 3 may thus serve both as a mechanical support and to electrically contact the semiconductor components 2. Furthermore, the assembly body 3 can be formed for the adjustment of the radiation characteristic of the lighting module. Overall, this results in an especially compact and cost-efficient lighting module.

For example, the lighting module may be provided to replace a fluorescent tube. To that end, the lighting module 1 is formed for insertion into a socket of a fluorescent tube. For example, the lighting module may have the outer shape of a fluorescent tube, in particular of a T2, T5 or T8 fluorescent tube.

This patent application claims the priority of the German patent application 10 2014 110 470.6, the disclosure of which is incorporated herein by reference.

The invention is not limited by the description by means of the exemplary embodiments. The invention rather includes any feature as well as any combination of features, which particularly includes any combination of features in the patent claims, even if this feature or this combination is not explicitly stated in the patent claims or the exemplary embodiments per se.

1. Lighting module with an assembly body, which extends between a rear side and a front side opposite the rear side, and with a plurality of semiconductor components, which are provided for the generation of radiation, wherein
the assembly body comprises, on the rear side, a plurality of recesses, in which the semiconductor components are arranged,
the assembly body is transmissive to the radiation generated in the semiconductor components and the radiation exits the front side of the assembly body,
a contact layer is arranged on the rear side of the assembly body, with which the semiconductor components are electrically conductively connected via connection lines, and
a reflector layer is arranged on the rear side of the assembly body, which completely covers at least the recesses.

2. Lighting module according to claim 1,
wherein the reflector layer and the contact layer together cover at least 90% of the rear side of the assembly body with reflective material.

3. Lighting module according to claim 1,
wherein interspaces between the semiconductor components and the assembly body are at least partially filled with a radiation-transmissive enclosure and wherein the reflector layer adjoins the enclosure on the side of the enclosure facing away from the front side of the assembly body.

4. Lighting module according to claim 1,
wherein the semiconductor components are semiconductor chips without housing and the connection lines are bond wires.

5. Lighting module according to claim 4,
wherein the semiconductor chips each comprise a radiation-transmissive substrate, through which the radiation exits the semiconductor chip and enters the assembly body via side surfaces of the recesses during operation of the semiconductor chip.

6. Lighting module according to claim 1,
wherein the front side of the assembly body runs in a curved manner at least in places.

7. Lighting module according to claim 6,
wherein the assembly body has a basic shape of a tubular segment.

8. Lighting module according to claim 6,
wherein the assembly body has a basic shape of a cylinder segment.

9. Lighting module according to claim 1,
wherein a radiation conversion material is present in a beam path between the semiconductor components and a radiation exit surface of the lighting module.

10. Lighting module according to claim 9,
wherein a minimum distance between the semiconductor components and the radiation conversion material is at least 10% of the center-to-center distance between two neighboring semiconductor components.

11. Lighting module according to claim 1,
wherein the lighting module comprises a radiation-transmissive body on the front side of the assembly body, which forms a radiation exit surface of the lighting module.

12. Lighting module according to claim 11,
wherein a radiation conversion material is arranged between the assembly body and the radiation-transmissive body.

13. Lighting module according to claim 11,
wherein the radiation-transmissive body comprises a roughening on the radiation exit surface.

14. Lighting module according to claim 11,
wherein the assembly body has a maximum extension along a direction running perpendicular to a longitudinal extension direction of the assembly body, which is at least 20% and at most 50% of the maximum extension of the radiation-transmissive body along this direction.

15. Lighting module according to claim 1,
wherein the assembly body contains a glass.

16. Lighting module according to claim 1,
wherein the lighting module is formed for the insertion into a socket for a fluorescent tube.

17. Lighting module with an assembly body, which extends between a rear side and a front side opposite the rear side, and with a plurality of semiconductor components, which are provided for the generation of radiation, wherein
the assembly body comprises, on the rear side, a plurality of recesses, in which the semiconductor components are arranged,
the assembly body is transmissive to the radiation generated in the semiconductor components and the radiation exits the front side of the assembly body,
the assembly body has a basic shape of a tubular segment,
a contact layer is arranged on the rear side of the assembly body, with which the semiconductor components are electrically conductively connected via connection lines, and
a reflector layer is arranged on the rear side of the assembly body, which completely covers at least the recesses.
